(19) United States
(12) Patent Application Publication
(10) Pub. No.: US 2017/0047200 A1
(43) Pub. Date: Feb. 16, 2017

(54) Plasma Processing Apparatus

(71) Applicant: Samsung Electronics Co., Ltd., Suwon-si (KR)

(72) Inventors: Hyung-Joo Lee, Hwaseong-si (KR); Kye-hyun Baek, Suwon-si (KR); Masayuki Tomoyasu, Seongnam-si (KR); Jong-seo Hong, Yongin-si (KR); Jin-pyoung Kim, Hwaseong-si (KR)

(21) Appl. No.: 15/097,365

(22) Filed: Apr. 13, 2016

(30) Foreign Application Priority Data
Aug. 11, 2015 (KR) 10-2015-0113375

(51) Int. Cl. H01J 37/32

(52) U.S. Cl. CPC H01J 37/3244; H01J 37/32082; H01J 37/32532; H01J 37/32642; H01J 2237/334

(57) ABSTRACT

A plasma processing apparatus includes a chamber defining a process space, an upper electrode mounted in the chamber, the upper electrode including a first gas spray port located in a central region of the upper electrode and a second gas spray port located in a peripheral region of the upper electrode, a lower electrode located opposite the upper electrode across the process space, a first gas supply unit configured to supply a first process gas into the process space via the first gas spray port and the second gas spray port, a second gas supply unit configured to supply a second process gas into the process space via the second gas spray port, a sensor configured to sense a state of plasma in an edge portion of the process space, and a controller configured to control the second gas supply unit in response to an output signal of the sensor.

### CROSS-REFERENCE TO RELATED APPLICATION

This application claims the benefit of Korean Patent Application No. 10-2015-0113375, filed on Aug. 11, 2015, the disclosure of which is incorporated by reference herein in its entirety.

### BACKGROUND

The inventive concept relates to a plasma processing apparatus, and more particularly, to a plasma processing apparatus provided for a seasoning process and an in-situ dry cleaning process for providing appropriate environments for a deposition process and an etching process.

In general, a semiconductor device is manufactured by using a plurality of unit processes, each of which includes depositing a thin layer and etching the thin layer. The etching process may be mainly performed in a semiconductor manufacturing system in which a plasma reaction is caused. Each time the accumulated usage time of the semiconductor manufacturing system equals a preset value, a polymer-based contaminant, which is generated on an inner wall of the chamber due to plasma, may be wet cleaned for preventive maintenance. Accordingly, immediately after the wet cleaning process, the chamber needs to undergo a seasoning process to stabilize the plasma reaction. Also, the chamber needs to undergo an in-situ dry cleaning (ISD) process to remove a by-product generated during a production process, such as a deposition process and an etching process.

### SUMMARY

The inventive concept provides a plasma processing apparatus configured to maintain an optimum state of a central portion of a chamber and reinforce the optimization of an edge portion of the chamber.

According to an aspect of the inventive concept, there is provided a plasma processing apparatus including a chamber defining a process space in which plasma is processed. An upper electrode is mounted in the chamber and includes a first gas spray port located in a central region of the upper electrode and a second gas spray port located in a peripheral region of the upper electrode. A lower electrode is located opposite the upper electrode across the process space. A first gas supply unit is configured to supply a first process gas into the process space via the first gas spray port and the second gas spray port. A second gas supply unit is configured to supply a second process gas into the process space via the second gas spray port. A sensor is configured to sense a state of plasma in an edge portion of the process space. A controller is configured to control the second gas supply unit in response to an output signal of the sensor.

The plasma processing apparatus may further include a splitter configured to split the first process gas supplied by the first gas supply unit into the first gas spray port and the second gas spray port.

The sensor may include a plasma sensor spaced apart from the upper electrode in a lateral direction and mounted in an upper portion of the chamber.

The plasma sensor may be an optical sensor or an electrical sensor.

The plasma processing apparatus may further include a focus ring configured to surround at least a portion of an outer circumference of a substrate mounted on the lower electrode.

The sensor may include a temperature sensor located under the focus ring.

The plasma processing apparatus may further include a focus ring heating unit configured to heat the focus ring.

The upper electrode may include a first upper electrode located in the central region of the upper electrode and a second upper electrode located in the peripheral region of the upper electrode and insulated from the first upper electrode.

The plasma processing apparatus may further include a radio-frequency (RF) power supply unit configured to supply power to the upper electrode. The RF power supply unit may include a power divider configured to distribute power supplied by the RF power supply unit among the first upper electrode and the second upper electrode.

The plasma processing apparatus may further include an RF power supply unit configured to supply power to the upper electrode. The RF power supply unit may include a first RF power supply unit configured to supply power to the first upper electrode and a second RF power supply unit configured to supply power to the second upper electrode.

The second process gas may be O₂ gas or CₓF_{y} gas.

According to another aspect of the inventive concept, there is provided a plasma processing apparatus including a chamber defining a process space in which plasma is processed. An upper electrode is mounted in the chamber and includes a first gas spray port located in a central region of the upper electrode and a second gas spray port located in a peripheral region of the upper electrode. A lower electrode is located opposite the upper electrode across the process space. An RF power supply unit is configured to supply power to the upper electrode. A focus ring is configured to surround at least a portion of an outer circumference of a substrate mounted on the lower electrode. A first gas supply unit is configured to supply a first process gas to the process space. A second gas supply unit is configured to supply a second process gas to an edge portion of the process space. A plasma sensor is mounted spaced apart from the upper electrode in a lateral direction. A temperature sensor is located under the focus ring. The second gas supply unit may be configured to supply the second process gas into the process space in response to output signals of the plasma sensor and the temperature sensor.

The plasma processing apparatus may further include a focus ring heating unit configured to heat the focus ring in response to the output signals of the plasma sensor and the temperature sensor.

The upper electrode may include a first upper electrode located in the central region of the upper electrode and a second upper electrode located in the peripheral region of the upper electrode and insulated from the first upper electrode. The RF power supply unit may be configured to distribute power among the first upper electrode and the second upper electrode in response to the output signals of the plasma sensor and the temperature sensor.

The plasma processing apparatus may be used in a seasoning process or an in-situ dry cleaning (ISD) process.

According to another aspect of the inventive concept, there is provided a plasma processing apparatus including a chamber defining a process space in which plasma is processed. An upper electrode is in the chamber. A first gas spray port is in a central region of the upper electrode. A second gas spray port is in a peripheral region of the upper electrode. A lower electrode facing the upper electrode is in the chamber. A first gas supply unit is configured to supply a first process gas to the process space through the first gas spray port and/or through the second gas spray port. At least one sensor is configured to sense a state of plasma in a peripheral portion of the process space. A second gas supply unit is configured to supply a second process gas to the peripheral portion of the process space through the second gas spray port in response to an output signal of the at least one sensor.

The plasma processing apparatus may include a focus ring surrounding at least a portion of an outer circumference of a substrate mounted on the lower electrode. The plasma processing apparatus may include a focus ring heating unit configured to heat the focus ring in response to the output signal of the at least one sensor.

The plasma processing apparatus may include a radio-frequency (RF) power supply unit configured to supply power to the upper electrode in response to the output signal of the at least one sensor.

The upper electrode may include a first upper electrode located in the central region of the upper electrode and a second upper electrode located in the peripheral region of the upper electrode and insulated from the first upper electrode.

The RF power supply unit may include a power divider configured to distribute power supplied by the RF power supply unit among the first upper electrode and the second upper electrode.

The RF power supply unit may include a first RF power supply unit configured to supply power to the first upper electrode and a second RF power supply unit configured to supply power to the second upper electrode.

### BRIEF DESCRIPTION OF THE DRAWINGS

Example embodiments of the inventive concept will be more clearly understood from the following detailed description taken in conjunction with the accompanying drawings in which:

FIG. 1 is a schematic diagram of a plasma processing apparatus according to an example embodiment;

FIG. 2 shows estimation results of critical dimensions (CDs), which are measured in a central portion and an edge portion of a wafer depending on whether a side tuning gas (STG) control knob or system is utilized;

FIGS. 3 and 4 are diagrams of a power control knob or system configured to control radio-frequency (RF) power to be applied to an upper electrode, according to an example embodiment;

FIG. 5 is a diagram of a temperature control knob or system configured to control a focus ring heating unit that is configured to heat a focus ring, according to an example embodiment;

FIG. 6 is a flowchart illustrating processes using a plasma processing apparatus according to an example embodiment; and

FIG. 7 is a flowchart illustrating a seasoning process and an in-situ dry-cleaning (ISD) process of FIG. 6.

### DETAILED DESCRIPTION OF THE EMBODIMENTS

The inventive concept will now be described more fully hereinafter with reference to the accompanying drawings, in which example embodiments of the inventive concept are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thicknesses of layers and regions are exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element or layer is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. Thus, a first element, component, region, layer or section discussed below could be termed a second element, component, region, layer or section without departing from the teachings of the inventive concept.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the inventive concept are described herein with reference to schematic illustrations of idealized embodiments of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. Hereinafter, at least one of embodiments may be combined.

A plasma processing apparatus according to example embodiments as described below may have various elements. Here, only necessary elements of the plasma processing apparatus will be exemplarily provided, and the inventive concept is not limited thereto.

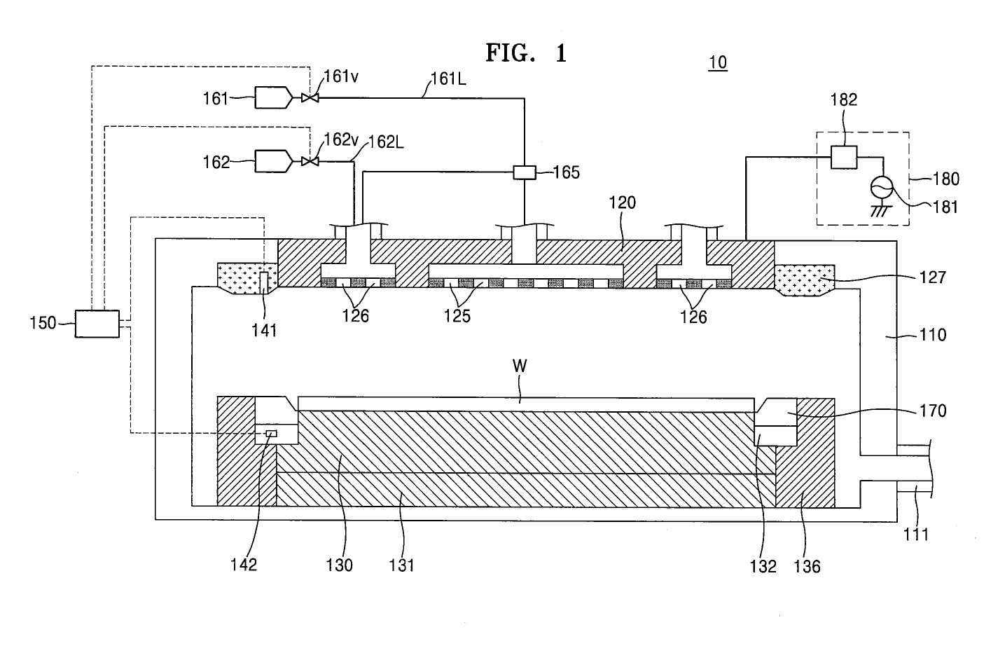

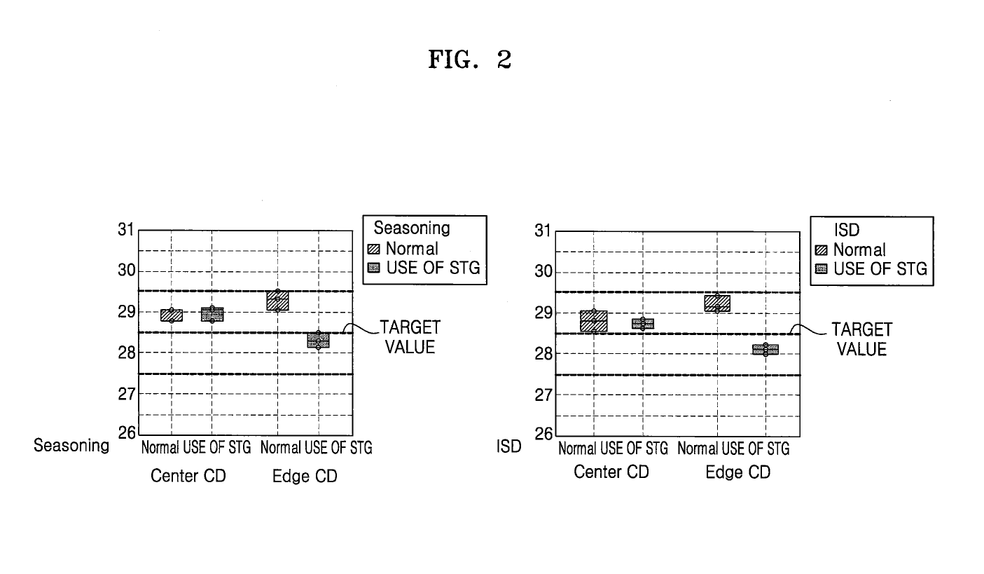

FIG. 1 is a schematic diagram of a plasma processing apparatus 10 according to an example embodiment. FIG. 2 shows estimation results of critical dimensions (CDs), which are measured in a central portion and an edge portion of a wafer W depending on whether a side tuning gas (STG) control knob or system is utilized.

Referring to FIG. 1, the plasma processing apparatus 10 may include a chamber 110, an upper electrode 120, a lower electrode 130, an upper edge ring 127, a focus ring 170, a first gas supply unit 161, a second gas supply unit 162, and sensors 141 and 142.

The chamber 110 may have an inner space that is isolated from the outside, and the inner space of the chamber 110 may be provided as a process space in which plasma is processed. The chamber 110 may include an etching chamber in which a wafer W or a thin layer formed on the wafer W is etched due to a plasma reaction. An etching process of patterning the wafer W or at least one thin layer of a silicon layer, an oxide layer, a nitride layer, and a metal layer formed on the wafer W may be performed in the chamber 110. The chamber 110 may be connected to a transfer chamber and a loadlock chamber, which may buffer a vacuum state.

An input/output (I/O) gate may be provided at one side of the chamber 110. Wafers W may be loaded into and unloaded from the chamber 110 via the I/O gate. Also, the chamber 110 may further include an exhaust duct 111 configured to exhaust a reaction gas or a reaction by-product. Although not specifically shown, the exhaust duct 111 may be connected to a vacuum pump and include a pressure control valve and a flow rate control valve.

The upper electrode 120 may be installed in the inner space of the chamber 110. The upper electrode 120 may receive process gases via the first and second gas supply units 161 and 162 and supply the process gases to the process space via first and second gas spray ports 125 and 126 formed in a bottom surface of the upper electrode 120. The upper edge ring 127 may be located to surround at least a portion of an outer circumference of the upper electrode 120.

In some embodiments, the first and second gas spray ports 125 and 126 may include the first gas spray port 125 located in a central region of the upper electrode 120 and the second gas spray port 126 located in a peripheral region of the upper electrode 120 surrounding the central region. That is, the second gas spray port 126 may be formed in a portion adjacent to an edge of the upper electrode 120. The process gas supplied via the first gas spray port 125 located in the central region of the upper electrode 120 may be mainly or primarily supplied to a central portion of the process space, while the process gas supplied via the second gas spray port 126 located in the peripheral region of the upper electrode 120 may be supplied to an edge or peripheral portion of the process space.

An RF power supply unit 180 may supply radio-frequency (RF) power for exciting the process gas supplied to the process space and generating plasma to the upper electrode 120. The power supply unit 180 may include an RF power source 181 and a matching device 182, and the matching device 182 may match plasma impedance with inner impedance of the RF power supply unit 180. The power supply unit 180 may supply an RF voltage of, for example, about 60 MHz, to the upper electrode 120.

The lower electrode 130 may be installed in the inner space of the chamber 110 and located opposite the upper electrode 120. A process space in which the wafer W mounted on one surface of the lower electrode 130 is processed may be provided between the upper electrode 120 and the lower electrode 130. The lower electrode 130 may include an electrostatic chuck configured to fix the wafer W by using static electricity. Also, the lower electrode 130 may be located on a support member 131 and configured to receive RF bias power.

The focus ring 170 may be located as a ring type to surround the wafer W mounted on the lower electrode 130. The focus ring 170 may function to support an edge of the wafer W supported by the lower electrode 130. The focus ring 170 may cover an edge of the lower electrode 130 and prevent a polymer compound generated during a process from penetrating the lower electrode 130 and forming impurity particles in the wafer W. Also, when an electric field is formed in the process space with application of RF power, the focus ring 170 may expand an electric field forming region and expand plasma. Thus, overall uniformity of a process performed on the wafer W may be improved.

A top surface of the focus ring 170 may have a stepped portion. A ring-shaped inner region of the focus ring 170 may have a smaller height than an outer region thereof and support the edge portion of the wafer W. The focus ring 170 may include, for example, any one of silicon (Si), silicon carbide (SiC), carbon (C), or a combination thereof

Meanwhile, an insulating member 132 may be provided under the focus ring 170. An insulating ring 136 may be provided to surround edges of the lower electrode 130 and the focus ring 170.

The first gas supply unit 161 may be configured to supply a first process gas to the first gas spray port 125 and the second gas spray port 126 formed in the upper electrode 120. The second gas supply unit 162 may be configured to supply a second process gas to the second gas spray port 126.

The first gas supply unit 161 may supply the first process gas via a first gas supply line 161L to the first gas spray port 125 and the second gas spray port 126, and the first gas supply line 161L may be branched and connected to the first gas spray port 125 and the second gas spray port 126. The first gas supply unit 161 may include a first control valve 161v, which may be configured to operate under the control of a controller 150.

The second gas supply unit 162 may supply the second process gas via a second gas supply line 162L, and the second gas supply line 162L may be connected to the second gas spray port 126 located in a peripheral region of the upper electrode 120. The second gas supply unit 162 may include a second control valve 162v, which may be configured to operate under the control of the controller 150. The second process gas sprayed via the second spray port 126 may be supplied to the edge portion of the process space.

In some embodiments, the first gas supply unit 161 may include a splitter 165 located at a point at which the first gas supply line 161L is branched. The splitter 165 may distribute the first process gas supplied from the first gas supply unit 161 among the first gas spray port 125 and the second gas spray port 126. The splitter 165 may distribute the first process gas among the first gas spray port 125 and the second gas spray port 126 in a ratio determined by determined conditions or a signal of the controller 150, which will be described later. The splitter 165 may include a flow rate control valve and adjust flow rates of gases supplied to the first gas spray port 125 and the second gas spray port 126. A flow rate of the first process gas supplied into the first gas spray port 125 and the second gas spray port 126 may be controlled by using the splitter 165 so that a distribution of plasma densities in the chamber 110 may be controlled.

Preventive maintenance, such as a wet cleaning process, may be performed to remove a polymer element, which is periodically generated as a by-product of an etching process. The polymer element may be deposited on an inner wall of the chamber 110 and components included in the chamber 110 every time a semiconductor production process is performed. When the polymer element is deposited to a predetermined thickness or more, the polymer element may fall as a lump from the inner wall of the chamber 110 on the wafer W, act as particles to contaminate the surface of the wafer W, and affect plasma generated in the process space. The preventive maintenance of the chamber 110 may be periodically performed each time the accumulated usage time of the chamber 110 reaches about 100 hours.

Directly after the preventive maintenance of the chamber 110, since etching characteristics of the wafer W or a thin layer are degraded, a process of seasoning the chamber 110 may be performed by using a bare wafer. For example, after the wet cleaning process of the chamber 110 is performed, a plasma reaction may be unstable or reproducibility of an etch rate of a thin layer may be reduced. The seasoning process may include a preliminary etching process of coating the inner wall of the chamber 110 with a polymer element. Also, the process of etching the wafer W may be followed by an in-situ dry cleaning (ISD) process. For example, the ISD process may prevent a by-product generated during the etching process from being deposited on the inner wall of the chamber 110 to cause a process drift and performance degradation. However, in the seasoning process and the ISD process for optimizing the chamber 110, the optimization of the edge portion of the process space may be unsatisfactory due to a difference in plasma density between the central portion and the edge portion of the process space in the chamber 110. Thus, according to example embodiments, the plasma processing apparatus 10 may utilize a control knob or system for sensing a state of plasma in the edge portion of the process space by using a sensor, monitor the state of plasma, and reinforce the optimization of the edge portion of the process space by using a seasoning process and an ISD process, as will be described in detail below.

In some embodiments, plasma processing apparatus 10 may include a plasma sensor 141 and a temperature sensor 142 to sense optimization of the edge portion of the process space. The plasma sensor 141 and the temperature sensor 142 may be configured to sense a state of plasma in the edge portion of the process space. The plasma sensor 141 may be mounted spaced apart from the upper electrode 120 in a lateral direction, and the temperature sensor 142 may be located below the focus ring 170.

The plasma sensor 141 may be mounted apart from the upper electrode 120 in a lateral direction. For example, the plasma sensor 141 may be mounted at the upper edge ring 127 surrounding upper electrode 120. The plasma sensor 141 may include an optical sensor and an electrical sensor.

The optical sensor may split light emitted from plasma and measure a composition state and variation of plasma at the edge portion of the process space. For example, the optical sensor may include an optical emission spectroscopy (OES) sensor. The optical sensor may include a window formed in a portion facing the process space so that the optical sensor may not be directly exposed to plasma.

The electrical sensor may be configured to measure electrical properties of plasma at the edge portion of the process space. For example, the electrical sensor may include a probe exposed to the process space. Since plasma acts as a resistor, current generated due to plasma may be measured by applying a voltage to the probe. Thus, plasma density of the edge portion of the process space may be measured.

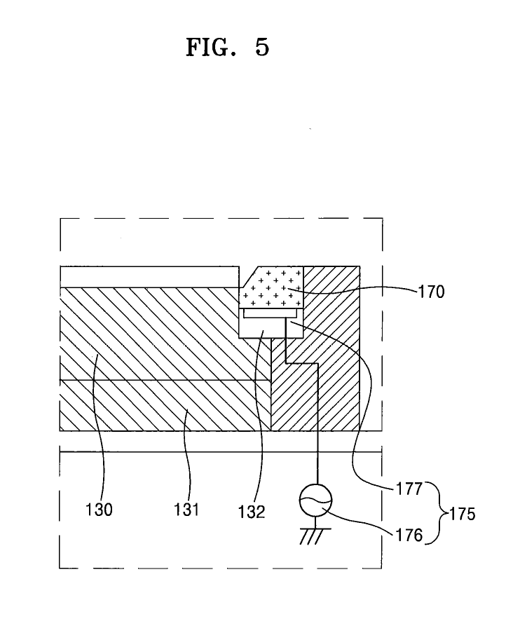

State information of plasma in the edge portion of the process space, which is detected by the plasma sensor 141, may be used as a feedback signal for controlling the second gas supply unit 162, the RF power supply unit 180, and the focus ring heating unit (refer to 175 in FIG. 5).

In addition, the temperature sensor 142 may be located below the focus ring 170 and measure a temperature of the focus ring 170. Since the focus ring 170 located adjacent to the edge portion of the process space indicates or shows a temperature of plasma of the edge portion of the process space, temperature information of plasma of the edge portion of the process space may be sensed by detecting a temperature of the focus ring 170. The temperature sensor 142 may not be directly exposed to plasma but located under the focus ring 170. For example, the temperature sensor 142 may be located in the insulating member 132. Similar to the plasma sensor 141, temperature information of the focus ring 170, which is detected by the temperature sensor 142, may be used as a feedback signal for controlling the second gas supply unit 162, the RF power supply unit 180, and the focus ring heating unit 175.

Information detected by the plasma sensor 141 and the temperature sensor 142 may be transmitted to the controller 150 via a signal transmission line. To optimize the edge portion of the process space based on output signals of the plasma sensor 141 and the temperature sensor 142, the controller 150 may control the second gas supply unit 162 to supply the second process gas to the edge portion of the process space, increase RF power supplied by the RF power supply unit 180, or control the focus ring heating unit 175 to heat the focus ring 170. The controller 150 may include a unit that receives measurement information of a sensor and monitors the measurement information. Also, the controller 150 may be connected to an external apparatus, such as a host computer, and transmit and receive data or a control signal. The controller 150 may include a computer system including a central processing unit (CPU) or a memory.

In some embodiments, to reinforce the optimization of the edge portion of the process space during the seasoning process and the ISD process, the controller 150 may control the second gas supply unit 162 by using the output signals of the plasma sensor 141 and the temperature sensor 142, and additionally supply the second process gas to the edge portion of the process space. That is, to optimize the edge portion of the process space without affecting the central portion of the process space, local optimization may be performed by using an STG control knob or system configured to supply an additional process gas to the edge portion of the process space.

While a process of optimizing the entire chamber is performed by using the first process gas supplied by the first gas supply unit 161, the STG control knob or system may control the second gas supply unit 162 to supply the second process gas to the edge portion of the process space, and perform local optimization on the edge portion of the process space. In this case, the second process gas may be the same as or different from the first process gas. For example, the seasoning process may include substantially the same process operations as an etching process, and the first process gas may be the same as a process recipe used in the etching process. Like the first process gas, the second process gas used for local optimization may be the same as the process recipe used in the etching process. Alternatively, the second process gas may be O₂ gas or CₓF_{y} gas (e.g., CF₄ or C₄F₆) unlike the first process gas. During the ISD process, the second process gas may be the same as or different from the first process gas. For example, the second process gas used in the ISD process may be O₂ gas or CₓF_{y} gas.

Referring to FIG. 2, a case in which the optimization process is performed by using the STG control knob or system may be compared with a case in which the optimization process is performed without using the STG control knob or system. Thus, it can be seen that the optimization of the edge portion of the process space is reinforced when the STG control knob or system is used.

To begin, CDs measured when the STG control knob or system was not used in a seasoning process will be examined. A CD measured in a region adjacent to the central portion of the process space approached a target CD, while a CD measured in a region adjacent to the edge portion of the process space comparatively deviated from the target CD and a distribution of CDs increased. That is, it can be confirmed that a non-uniform seasoning process was performed due to a difference in plasma density between the central portion and the edge portion of the process space. In contrast, when the STG control knob or system was used in a seasoning process, CDs measured in both the central portion and the edge portion of the process space approached the target CD.

When the STG control knob or system is used in an ISD process, it can be confirmed that estimation results of CDs show a similar tendency to the estimation results of CDs measured in the seasoning process. After the ISD process was performed without using the STG control knob or system, when an etching process was performed, a CD measured in the edge portion of the process space deviated from a target CD more than a CD measured in the central portion of the process space. In contrast, when the STG control knob or system is used in the ISD process, it can be confirmed that a CD measured in the edge portion of the process space more closely approached a target CD.

Based on the estimation results of CDs, it can be seen that when the inside of the chamber 110 is optimized by performing a seasoning process and an ISD process using the STG control knob or system, the influence upon the central portion of the process space may be minimized or reduced, and the optimization of the edge portion of the process space may be improved or reinforced. By use of the STG control knob or system, a deviation in an etching process performed on the edge of the wafer W may be reduced. Thus, a drop in yield may be improved in the edge of the wafer W, and the overall yield may be improved. Furthermore, the optimization of the inside of the chamber 110 may be effectively performed so that a preventive maintenance cycle may be extended to improve productivity and reduce costs.

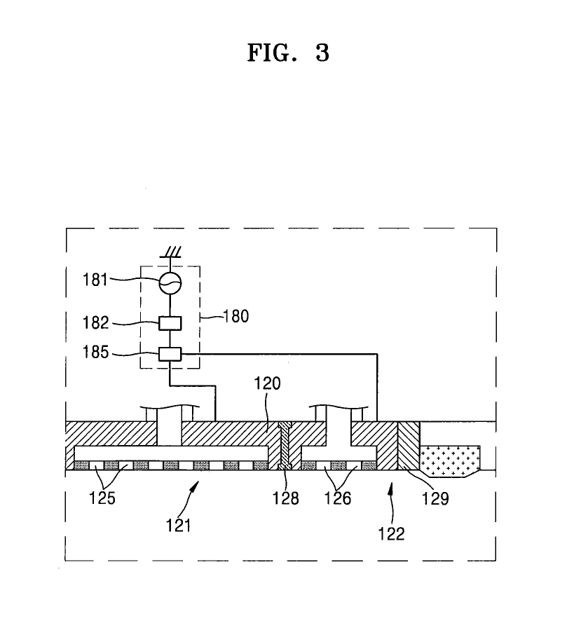

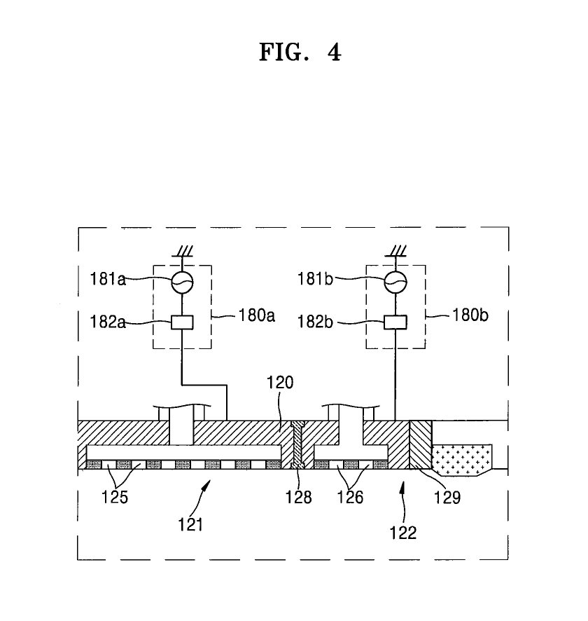

FIGS. 3 and 4 are diagrams for explaining a power control knob or system configured to control RF power applied to an upper electrode 120, according to an example embodiment.

Referring to FIGS. 1 and 3, when a seasoning process and an ISD process are performed, to reinforce the optimization of the edge portion of the process space, the controller 150 may use the power control knob or system, which may control power applied to the upper electrode 120 by using the output signals of the plasma sensor 141 and the temperature sensor 142 and increase the intensity of an electric field formed in the edge portion of the process space.

In some embodiments, the upper electrode 120 may include a first upper electrode 121 located in a central region of the upper electrode 120 and a second upper electrode 122 located in a peripheral region of the upper electrode 120 and insulated from the first upper electrode 121. For example, a dielectric material 128 may be located inside the second upper electrode 122, and an insulating shielding member 129 may be located outside the second upper electrode 122. Accordingly, each of the first upper electrode 121 and the second upper electrode 122 may generate an electric field in the process space. The intensities of electric fields formed in the central portion and the edge portion of the process space may be controlled by adjusting RF power applied to the first upper electrode 121 and the second upper electrode 122.

In some embodiments, the RF power supply unit 180 may include a power divider 185 configured to supply RF power to the upper electrode 120 and distribute the RF power among the first upper electrode 121 and the second upper electrode 122. The controller 150 may be configured to control the RF power supply unit 180 in response to output signals received from the plasma sensor 141 and the temperature sensor 142. When plasma density in the edge portion of the process space is relatively low, the controller 150 may be configured to increase RF power applied to the second upper electrode 122. In this case, plasma in the edge portion of the process space may be controlled by adjusting RF power applied to the second upper electrode 122. Since the second upper electrode 122 is electrically insulated from the first upper electrode 121, influence upon plasma in the central portion of the process space may be minimized.

The power divider 185 may be electrically connected to the first upper electrode 121 and the second upper electrode 122 via a conductive member. The conductive member configured to connect the power divider 185 and the first upper electrode 121 may include a variable condenser, and a capacitance of the variable condenser may be variably controlled. By controlling the capacitance of the variable condenser, RF powers supplied to the first upper electrode 121 and the second upper electrode 122 may be controlled, and a distribution of plasma densities in the chamber 110 may be controlled.

Referring to FIGS. 1 and 4, the RF power supply unit 180 may include a first RF power supply unit 180a configured to supply RF power to the first upper electrode 121 and a second RF power supply unit 180b configured to supply RF power to the second upper electrode 122. The first RF power supply unit 180a and the second RF power supply unit 180b may include matching devices 182a and 182b, respectively.

The controller 150 may be configured to control the first RF power supply unit 180a and the second RF power supply unit 180b in response to the output signals received from the plasma sensor 141 and the temperature sensor 142. When plasma density in the edge portion of the process space is relatively low, the controller 150 may be configured to control the second RF power supply unit 180b and increase RF power applied to the second upper electrode 122.

FIG. 5 is a diagram of a temperature control knob or system configured to control a focus ring heating unit 175 for heating a focus ring 170 according to an example embodiment.

Referring to FIGS. 1 and 5, when a seasoning process and an ISD process are performed, to enhance the optimization of an edge portion of the process space, a controller 150 may be a thermal control knob or system, which may control a focus ring heating unit 175 by using output signals of sensors 141 and 142 and heat the focus ring 170.

The focus ring 170 may be heated by the focus ring heating unit 175. For example, the focus ring heating unit 175 may include a heating power source 176 and a heating electrode 177 provided under the focus ring 170. The heating electrode 177 may be located in an insulating member 132 located under the focus ring 170. The heating electrode 177 may extend along a bottom surface of the focus ring 170. The heating electrode 177 may include a coil. The focus ring 170 may be heated due to an induced magnetic field formed by supplying current to the coil. However, configuration of the focus ring heating unit 175 is not limited thereto, and various configurations may be used to heat the focus ring 170.

The controller 150 may be configured to control the focus ring heating unit 175 by using the above-described output signals received from the plasma sensor 141 and the temperature sensor 142. When a temperature of plasma in the edge portion of the process space is low, the edge portion of the process space may be optimized by heating the focus ring 170.

The focus ring heating unit 175 may be used for a process (e.g., the seasoning process or the ISD process) for optimizing the inner wall of the chamber 110 and components of the chamber 110. The focus ring 170 may be heated to raise the temperature of plasma in the process space during a semiconductor production process (e.g., an etching process). However, in this case, since the heating of the focus ring 170 affects a central portion of the process space adjacent to the focus ring 170, it may be difficult to precisely control the etching process. In contrast, since an optimization process does not require a high precision unlike the etching process, even if a state of plasma in the central portion of the process space is minutely or slightly changed due to the heating of the focus ring 170, there may be little problem with such a minor change. Accordingly, the optimization process, such as a seasoning process or an ISD process, may positively utilize the temperature control knob or system configured to heat the focus ring 170 and control a temperature of plasma in the process space.

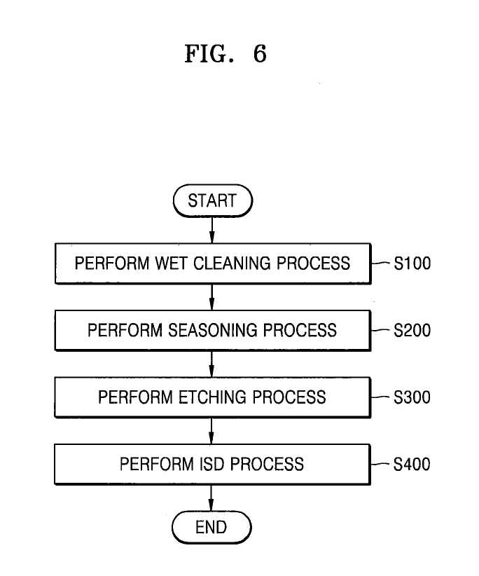

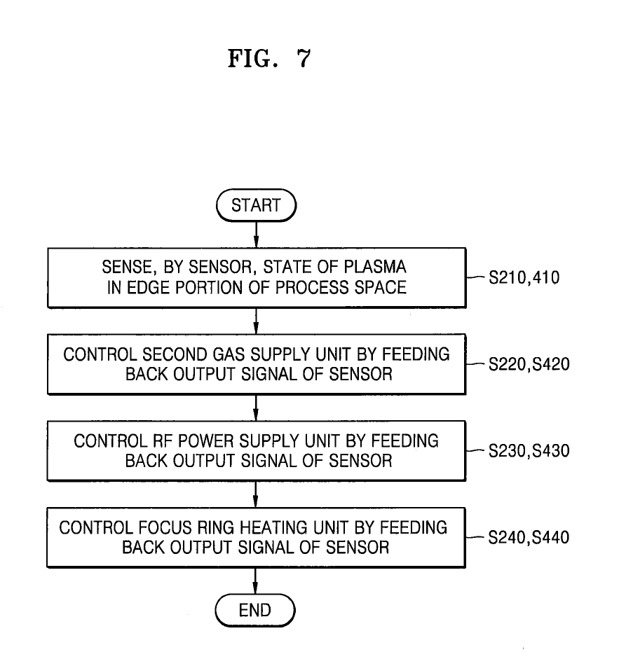

FIG. 6 is a flowchart of processes using a plasma processing apparatus according to an example embodiment. FIG. 7 is a flowchart of a seasoning process and an ISD process of FIG. 6.

Referring to FIGS. 1 to 7, a wet cleaning process may be performed to remove a polymer that is generated as a by-product during an etching process (S100). Since the polymer deposited on an inner wall of the chamber 110 or components included in the chamber 110 acts as particles that contaminate the inside of the chamber 110, the polymer may be removed by using a wet cleaning process.

Thereafter, a seasoning process may be performed (S200). To remove moisture, which occurs during the wet cleaning process and remains in the chamber 110, and provide appropriate environments for an etching process, a seasoning process of forming a CO₂ layer on the inner wall of the chamber 110 and components included in the chamber 110 may be performed to optimize the inside of the chamber 110. The seasoning process may be performed while a bare wafer is being mounted on the lower electrode 130, and the bare wafer W may help prevent the lower electrode 130 from being damaged during the seasoning process.

After the inside of the chamber 110 is optimized by using the seasoning process, a wafer on which an etching process is to be performed may be loaded into the chamber 110, and the etching process may be performed (S300).

To remove a by-product generated during the etching process, an ISD process may be performed (S400). The ISD process may be performed while the bare wafer is being mounted on the lower electrode 130. Due to the ISD process, a by-product deposited on the inner wall of the chamber 110 may be removed to help prevent a process drift. After the ISD process, an etching process may be performed again. After the etching process is performed several times, preventive maintenance, such as a wet cleaning process, may be performed again.

Here, the operation S200 of performing the seasoning process and the operation S400 of performing the ISD process may be performed with reference to the process shown in FIG. 7 to reinforce the optimization of an edge portion of a process space of the chamber 110.

To begin, a plasma state of the edge portion of the process space may be sensed by using the plasma sensor 141 and the temperature sensor 142 (S210 and S410). The plasma state of the edge portion of the process space may be sensed by using the plasma sensor 141 mounted apart from the upper electrode 120 in a lateral direction. Also, a temperature of plasma of the edge portion of the process space may be measured by the temperature sensor 142 configured to measure a temperature of the focus ring 170.

An STG control knob or system, a power control knob or system, and a temperature control knob or system may be used to reinforce the optimization of the edge portion of the process space, based on information measured by the plasma sensor 141 and the temperature sensor 142.

The STG control knob or system may control the second gas supply unit 162 by feeding back the output signals of the plasma sensor 141 and the temperature sensor 142, and additionally supply a second process gas to the edge portion of the process space (S220 and S420). In this case, a kind, flow velocity, and flow rate of the second process gas may be determined by monitoring information measured by the plasma sensor 141 and the temperature sensor 142.

The power control knob or system may control an RF power supply unit 180 by feeding back the output signals of the plasma sensor 141 and the temperature sensor 142, increase RF power applied to the second upper electrode 122, and increase the intensity of an electric field generated in the edge portion of the process space (S230 and S430). Since the second upper electrode 122 adjacent to the edge portion of the process space is insulated from the first upper electrode 121, the optimization of the edge portion of the process space may be reinforced by maintaining the optimization of a central portion of the process space. In this case, the power control knob or system may control the power divider 185 capable of distributing RF power supplied by the power supply unit 180 among the first upper electrode 121 and the second upper electrode 122 or control the second RF power supply unit 180b to supply RF power to the second upper electrode 122.

The temperature control knob or system may control the focus ring heating unit 175 by feeding back the output signals of the plasma sensor 141 and the temperature sensor 142, heat the focus ring 170, and increase a temperature of plasma in the edge portion of the process space (S240 and S440).

However, the STG control knob or system, the power control knob or system, and the temperature control knob or system may be used simultaneously or separately. Alternatively, only some of the STG control knob or system, the power control knob or system, and the temperature control knob or system may be selectively used.

In an example embodiment, the operations S210 and S410 of using the STG control knob or system in the seasoning process and the ISD process may be performed according to the following process recipe.

To begin, a seasoning process recipe may follow the same order as a production process recipe. For example, the seasoning process recipe may be performed in the order of a production process recipe used in an oxide mask etching process. However, a seasoning process may be performed by using the STG control knob or system to reinforce the optimization of the edge portion of the process space. For instance, the oxide mask etching process may include four stages, specifically, SOH (or an operation of etching a SOH layer), SOH₂ (or an over-etching operation), oxide (or an operation of etching an oxide layer), and BT (or an operation of removing a residue) and utilize a STG control knob or system.

TABLE 1

| | | | Second |
|---|---|---|---|
| | | | gas supply |
| | | | unit |
| | | First gas supply | (STG control) |
| | Pressure (mTorr) | unit (SCCM) | (SCCM) |
| SOH | 10 | 20C₄F₈, 100O₂, 23COS | 10O₂ |
| SOH₂ | 10 | 100O₂, 30COS | 10O₂ |
| Oxide | 10 | 25C₄F₈, 28O₂, 25CH₂F₂ | 10O₂ |
| BT | 40 | 130CF₄, 8O₂ | 10O₂ |

A SOH seasoning process recipe may include supplying C₄F₈ at a flow rate of 20 sccm, supplying O₂ at a flow rate of 100 sccm, supplying COS at a flow rate of 23 sccm, and applying a pressure of 10 mTorr, and STG control may include supplying O₂ at a flow rate of 10 sccm. A SOH seasoning process may be performed for about 15 seconds, and an RF of about 650 W to about 750 W may be supplied.

A SOH₂ seasoning process recipe may include supplying O₂ at a flow rate of 100 sccm, supplying COS at a flow rate of 30 sccm, and applying a pressure of 10 mTorr, and STG control may include supplying O₂ at a flow rate of 10 sccm. A SOH₂ seasoning process may be performed for about 30 seconds, and an RF power of about 650 W to about 750 W may be supplied.

An oxide seasoning process recipe may include supplying C₄F₈ at a flow rate of 25 sccm, supplying 02 at a flow rate of 28 sccm, supplying CH₂F₂ at a flow rate of 25 sccm, and applying a pressure of 10 mTorr, and STG control may include supplying O₂ at a flow rate of 10 sccm. An oxide seasoning process may be performed for about 60 seconds, and an RF power of about 450 W to about 550 W and a bias power source of about 1000 W may be supplied.

A BT seasoning process recipe may include supplying CF₄ at a flow rate of 130 sccm, supplying O₂ at a flow rate of 8 sccm, and a pressure of about 40 mTorr, and STG control may include supplying O₂ at a flow rate of 10 sccm. A BT seasoning process may be performed for about 20 seconds, and an RF power of about 350 W to about 450 W may be supplied.

Accordingly, after the preventive maintenance including a wet cleaning process, a seasoning process including four stages may be performed on the chamber 110 in which the four stages of the etching process of the semiconductor production process are sequentially performed. After the seasoning process is repeated for a predetermined amount of time, the seasoning process may be directly shifted into the semiconductor production process.

TABLE 2

| | | | second gas |
|---|---|---|---|
| | | | supply unit |
| | | | (STG control) |
| | Pressure (mTorr) | first gas supply unit (SCCM) | (SCCM) |
| ISD | 500 | 2000O₂ | 10O₂ |

In addition, an ISD process recipe may include supplying O₂ at a flow rate of 2000 sccm and applying a pressure of 500 mTorr, and STG control may include supplying O₂ at a flow rate of 10 sccm. The ISD process may be performed for about 7 seconds, and an RF power of about 700 W to about 800 W and a bias power source of about 50 W may be supplied.

Accordingly, an ISD process may be immediately performed on the chamber 110 in which an etching process is performed. After the ISD process is repeated for a predetermined time, the ISD process may be immediately shifted into a semiconductor production process.

The above-described seasoning process and ISD process may be examples of a specific etching process and employ various other process recipes than the above-described recipes.

However, the plasma processing apparatus may be used not only in an optimization process (e.g., a seasoning process and an ISD process), but also in various processes (e.g., an etching process and a thin film forming process) of processing a wafer by using plasma.

While the inventive concept has been particularly shown and described with reference to example embodiments thereof, it will be understood that various changes in form and details may be made therein without departing from the spirit and scope of the following claims.

What is claimed is:

1. A plasma processing apparatus comprising:
a chamber defining a process space in which plasma is processed;
an upper electrode mounted in the chamber, the upper electrode including a first gas spray port located in a central region of the upper electrode and a second gas spray port located in a peripheral region of the upper electrode;
a lower electrode located opposite the upper electrode across the process space;
a first gas supply unit configured to supply a first process gas to the process space via the first gas spray port and the second gas spray port;
a second gas supply unit configured to supply a second process gas to the process space via the second gas spray port;
a sensor configured to sense a state of plasma in an edge portion of the process space; and
a controller configured to control the second gas supply unit in response to an output signal of the sensor.

2. The apparatus of claim 1, further comprising a splitter configured to distribute the first process gas supplied by the first gas supply unit among the first gas spray port and the second gas spray port.

3. The apparatus of claim 1, wherein the sensor comprises a plasma sensor spaced apart from the upper electrode in a lateral direction and mounted in an upper portion of the chamber.

4. The apparatus of claim 3, wherein the plasma sensor is an optical sensor or an electrical sensor.

5. The apparatus of claim 1, further comprising a focus ring configured to surround at least a portion of an outer circumference of a substrate mounted on the lower electrode.

6. The apparatus of claim 5, wherein the sensor comprises a temperature sensor located under the focus ring.

7. The apparatus of claim 5, further comprising a focus ring heating unit configured to heat the focus ring.

8. The apparatus of claim 1, wherein the upper electrode comprises a first upper electrode located in the central region of the upper electrode and a second upper electrode located in the peripheral region of the upper electrode and insulated from the first upper electrode.

9. The apparatus of claim 8, further comprising a radio-frequency (RF) power supply unit configured to supply power to the upper electrode,
wherein the RF power supply unit comprises a power divider configured to distribute power supplied by the RF power supply unit among the first upper electrode and the second upper electrode.

10. The apparatus of claim 8, further comprising an RF power supply unit configured to supply power to the upper electrode,
wherein the RF power supply unit comprises a first RF power supply unit configured to supply power to the first upper electrode and a second RF power supply unit configured to supply power to the second upper electrode.

11. The apparatus of claim 1, wherein the second process gas is O₂ gas or CₓF_{y} gas.

12. A plasma processing apparatus comprising:
a chamber defining a process space in which plasma is processed;
an upper electrode mounted in the chamber, the upper electrode including a first gas spray port located in a central region of the upper electrode and a second gas spray port located in a peripheral region of the upper electrode;
a lower electrode located opposite the upper electrode across the process space;
a radio-frequency (RF) power supply unit configured to supply power to the upper electrode;
a focus ring configured to surround at least a portion of an outer circumference of a substrate mounted on the lower electrode;
a first gas supply unit configured to supply a first process gas to the process space;
a second gas supply unit configured to supply a second process gas to an edge portion of the process space;
a plasma sensor mounted spaced apart from the upper electrode in a lateral direction; and
a temperature sensor located under the focus ring,
wherein the second gas supply unit is configured to supply the second process gas to the process space in response to output signals of the plasma sensor and the temperature sensor.

13. The apparatus of claim 12, further comprising a focus ring heating unit configured to heat the focus ring in response to the output signals of the plasma sensor and the temperature sensor.

14. The apparatus of claim 12, wherein the upper electrode comprises a first upper electrode located in the central region of the upper electrode and a second upper electrode located in the peripheral region of the upper electrode and insulated from the first upper electrode,
wherein the RF power supply unit is configured to distribute power among the first upper electrode and the second upper electrode in response to the output signals of the plasma sensor and the temperature sensor.

15. The apparatus of claim 12, wherein the plasma processing apparatus is used in a seasoning process or an in-situ dry cleaning (ISD) process.

16. A plasma processing apparatus comprising:
a chamber defining a process space in which plasma is processed;
an upper electrode in the chamber;
a first gas spray port in a central region of the upper electrode;
a second gas spray port in a peripheral region of the upper electrode;
a lower electrode facing the upper electrode in the chamber;
a first gas supply unit configured to supply a first process gas to the process space through the first gas spray port and/or through the second gas spray port;
at least one sensor configured to sense a state of plasma in a peripheral portion of the process space; and
a second gas supply unit configured to supply a second process gas to the peripheral portion of the process space through the second gas spray port in response to an output signal of the at least one sensor.

17. The apparatus of claim 16 further comprising:
a focus ring surrounding at least a portion of an outer circumference of a substrate mounted on the lower electrode; and
a focus ring heating unit configured to heat the focus ring in response to the output signal of the at least one sensor.

18. The apparatus of claim 16, further comprising a radio-frequency (RF) power supply unit configured to supply power to the upper electrode in response to the output signal of the at least one sensor.

19. The apparatus of claim 18, wherein the upper electrode comprises a first upper electrode located in the central region of the upper electrode and a second upper electrode located in the peripheral region of the upper electrode and insulated from the first upper electrode, and wherein the RF power supply unit comprises a power divider configured to distribute power supplied by the RF power supply unit among the first upper electrode and the second upper electrode.

20. The apparatus of claim 18, wherein the upper electrode comprises a first upper electrode located in the central region of the upper electrode and a second upper electrode located in the peripheral region of the upper electrode and insulated from the first upper electrode, and wherein the RF power supply unit comprises a first RF power supply unit configured to supply power to the first upper electrode and a second RF power supply unit configured to supply power to the second upper electrode.
